(19) United States
(12) Patent Application Publication
(10) Pub. No.: US 2025/0219624 A1
(43) Pub. Date: Jul. 3, 2025

(54) SLEW RATE PROTECTION CIRCUIT

(71) Applicant: Cambridge GaN Devices Limited, Cambridge (GB)

(72) Inventors: Sheung Wai FUNG, Cambourne (GB); Martin ARNOLD, Cambridge (GB); Tara VISHIN, Eddington (GB)

(21) Appl. No.: 18/999,022

(22) Filed: Dec. 23, 2024

(30) Foreign Application Priority Data
Dec. 27, 2023 (GB) 2320056.1

(51) Int. Cl. H03K 5/04

(52) U.S. Cl. CPC H03K 5/04

(57) ABSTRACT

A power integrated circuit comprising at least one III-nitride high voltage high-electron-mobility transistor (power HEMT), the power HEMT comprising a heterojunction formed between a GaN layer and an AlGaN layer, and a slew rate protection circuit. The slew rate protection circuit comprising a clamping transistor electrically connected between a gate terminal and a source terminal of the power HEMT, and a detection circuit electrically connected between a drain terminal and the source terminal of the power HEMT, wherein an output of the detection circuit is electrically connected to a gate terminal of the clamping transistor. The detection circuit is configured to output a signal to turn-on the clamping transistor when a transient voltage greater than a threshold transient voltage is observed across the drain and the source terminals of the power HEMT.

The present application claims priority to United Kingdom Application No. 2320056.1, filed Dec. 27, 2023, the entire contents of which is incorporated herein for all purposes by this reference.

### FIELD OF THE DISCLOSURE

The present disclosure relates to semiconductor devices. Particularly, but not exclusively, the disclosure relates to hetero-structure AlGaN/GaN high electron mobility transistors or rectifiers.

### BACKGROUND OF THE DISCLOSURE

Gallium Nitride (GaN) is a wide band gap material with properties that make it a suitable candidate for use in several fields of application which require or benefit from the use of solid-state devices (e.g. radio-frequency electronics, opto-electronics, power electronics).

GaN technology allows transistors with high electron mobility and high saturation velocity to be designed. These properties of GaN have made it a good candidate for high-power and high-temperature microwave applications, for example radar and cellular communications systems.

Additionally, GaN with its wide bandgap offers the potential for emitting light at higher frequencies for example the green (˜495 nm-570 nm), blue (˜450 nm-495 nm), violet (˜380 nm-450 nm), and ultraviolet (˜100 nm-400 nm) portions of the electromagnetic spectrum.

Gallium Nitride (GaN) has been more recently considered as a very promising material for use in the field of power devices. The application areas range from portable consumer electronics, solar power inverters, electric vehicles, and power supplies. The wide band gap of the material (Eg=3.39 eV) results in a high critical electric field (Ec=3.3 MV/cm) which can lead to the design of devices with a shorter drift region, and therefore lower on-state resistance, compared to a silicon-based device with the same breakdown voltage.

The use of an Aluminium Gallium Nitride (AlGaN)/GaN heterostructure also allows the formation of a two-dimensional electron gas (2DEG) at the hetero-interface where carriers can reach very high mobility (μ=2000 cm2/(Vs)) values. In addition, the piezopolarization charge present at the AlGaN/GaN heterostructure, results in a high electron density in the 2DEG layer (e.g. 1×1013cm−2). These properties allow the development of High Electron Mobility Transistors (HEMTs) and Schottky barrier diodes with very competitive performance parameters. One common parameter used to compare power semiconductor transistors is Specific ON-state resistance or Specific Rds(ON). Where specific Rds(ON) is often the product of the resistance of a device times the area of the device on wafer. An extensive amount of research has focused on the development of power devices using AlGaN/GaN heterostructures.

Additionally, the use of GaN devices can lead to lower switching losses, thus allowing an increase in switching frequency and therefore an overall increase in power density and efficiency of power conversion equipment. For the same ON-state Rds(ON) resistance, GaN power devices may generally have lower input and output capacitances, compared to silicon IGBTs and MOSFETs, leading to faster switching speeds with higher dV/dt signals experienced across the terminals of the device. While this is beneficial in many applications, it can lead to unwanted oscillations due to parasitic components present both at the device and circuit level. A proposed solution in order to avoid the oscillatory behaviour is to add an external gate resistance to the device in order to reduce the dV/dt and dl/dt rate observed (L. Efthymiou et al, On the Source of Oscillatory Behaviour during Switching of Power Enhancement Mode GaN HEMTs, Energies, vol. 10, no. 3, 2017). However, added external gate resistance may extend the switching period and increase the overall switching losses of the device.

The dV/dt values, also known as voltage slew rate, of power-switching devices is caused by the interaction between the various parasitic capacitances and gate-drive circuit impedances and it is determined by the charge and discharge rate of the power device capacitance and any capacitance of the circuit in which the power device is operating in. High slew rates are typically common in bridge topologies with high voltages buses and this phenomenon is aggravated by the high switching speed of the Gallium Nitride technology. There are various strategies proposed in the prior art to improve the dV/dt immunity.

A solution to improve dV/dt immunity is the monolithic integration of an active Miller clamp. The active Miller clamp is a transistor connected between the gate and source terminal of the power device. The combination of a power transistor and other monolithically integrated components is intended to provide sensing and protection function is often described as a power integrated circuit (IC). In operation, the active Miller clamp is intended to be in the on-state when the power device is in the off-state in order to provide a low impedance path between the gate and source terminal of the power device. This can ensure that any parasitic turn-on effects during the off-state operation or turn-off of the power device are limited. The active Miller clamp is further intended to be in the off-state when the power device is in the on-state in order to permit a gate drive voltage to be established between the gate and source terminal of the power device. The active Miller clamp is therefore required to switch between an on-state and an off-state and generally requires a switching drive signal to be applied to its gate. The active Miller clamp driver is commonly powered from a fixed voltage supply. The driver may often be an inverter with the control signal (or a level shifter version of the control signal) driving the power device as an input.

US patent application publication no. 2023/0131602 proposed a heterojunction power device in combination with an auxiliary gate region with an auxiliary two-dimensional carrier gas (e.g. 2DEG) region. The heterojunction power device may further comprise an active Miller clamp to offer an additional pull-down network for the active (high voltage) device gate terminal during the device turn-off transient. However, broadly speaking, an active Miller clamp circuit may operate more effectively when the voltage (Vdd) is established to power the driving circuit of the active Miller clamp. In the absence of Vdd, high dV/dt values during switching transients across the device can potentially result in false turn-on of the transistor. In a typical half bridge topology this may result in shoot through (R. Xie, H. Wang, G. Tang, X. Yang and K. J. Chen, “An Analytical Model for False Turn-On Evaluation of High-Voltage Enhancement-Mode GaN Transistor in Bridge-Leg Configuration,” in IEEE Transactions on Power Electronics, vol. 32, no. 8, pp. 6416-6433 August 2017, doi: 10.1109/TPEL.2016.2618349).

The Applicant has therefore recognised a need for an alternative solution that can help in providing dV/dt ruggedness during non-operating times of a Miller clamp.

### SUMMARY

It is the object of this invention to provide a slew rate protection circuit which can provide the same or superior protection that a monolithically integrated active Miller clamp transistor provides against false turn-on, without the need of an established voltage supply (VDD) to do so. The slew rate protection circuit may facilitate the protection of the power device in a power integrated circuit (IC) from false turn-on due to fast transients across its output terminals (e.g. drain, source).

The slew rate protection circuit (or a section thereof) may only be operational during a short period of operation before a voltage supply (VDD) which can power the driver of an active Miller clamp is established. VDD may be an externally applied voltage or a regulated voltage generated on the power IC. The slew rate protection circuit may be disabled once the voltage supply for the drive of an active Miller clamp is established.

Overall, this may allow the design of a device with improved robustness against false turn-on under all periods of operation, including during start-up before voltage supplies and/or regulated voltages are established in a power electronics circuit.

According to a first aspect of the present disclosure there is provided a power integrated circuit comprising:

at least one Ill-nitride high voltage high-electron-mobility transistor (power HEMT), the power HEMT comprising a heterojunction formed between a GaN layer and an AlGaN layer; and

a slew rate protection circuit comprising:
a clamping transistor electrically connected between a gate terminal and a source terminal of the power HEMT;
a detection circuit electrically connected between a drain terminal and the source terminal of the power HEMT, wherein an output of the detection circuit is electrically connected to a gate terminal of the clamping transistor; and
wherein the detection circuit is configured to output a signal to turn-on the clamping transistor when a transient voltage greater than a threshold transient voltage is observed across the drain and the source terminals of the power HEMT.

Thus, described herein is a power integrated circuit comprising a first main terminal, a second main terminal, and a control terminal. The power integrated circuit further comprises a semiconductor switch comprising:

an III-nitride high voltage high-electron-mobility transistor (HEMT), featuring at least three terminals, source, drain and gate and having at least one GaN layer and at least one AlGaN layer and at least one heterojunction formed between the at least one GaN layer and the at least one AlGaN layer; and

a slew rate protection circuit further comprising:

an enhancement or depletion mode clamping transistor connected between the gate and source of the power HEMT;

an (edge) detection circuit connected between the drain and source of the power HEMT, wherein an output of the edge detection circuit connected to the gate terminal of the enhancement mode clamping transistor;

wherein the detection circuit is configured to turn on the enhancement mode clamping transistor when a fast positive dv/dt is observed across the terminal of the power HEMT.

The detection circuit may be configured to turn on the enhancement mode clamping transistor only when a voltage supply is absent. For example, the slew rate protection circuit may further comprise a disable circuit which can disable the operation of the detection circuit when a voltage supply is present. The disable circuit may comprise is a disable transistor connected across the enhancement mode clamping transistor gate and source.

In examples, the detection circuit comprises a passive differentiator, i.e. a capacitor and resistor in series and the mid-point is the output of the edge detection circuit. Alternatively, the detection circuit comprises a source-gate connected transistor and a resistor in series and the mid-point is the output of the edge detection circuit.

The output of the detection circuit may be connected to the gate of the enhancement mode clamping transistor through a high-voltage diode.

In examples, the power integrated circuit is a III-nitride power integrated circuit with all the components monolithically integrated. Alternatively, the slew rate protection circuit may be incorporated on a silicon chip co-packaged with a III-nitride chip, the III nitride chip incorporating the power HEMT and the clamping transistor (such as a Miller Clamp).

In examples, the power integrated circuit further comprises an interface circuit operatively connected between the control terminal of the power integrated circuit and the gate of the power HEMT. The interface circuit may be part of the power integrated circuit or part of a separate III-nitride or silicon circuit.

The power integrated circuit may further comprise a drive circuit for the clamping transistor, such as an inverter circuit, operatively connected to the gate of the clamping transistor. The drive circuit may be operated/powered by a (e.g. external) voltage supply. Alternatively, the power integrated circuit may comprise a second clamping transistor (e.g. a Miller clamp) also connected between the gate and source of the power HEMT, and the drive circuit may be a drive circuit for the second clamping transistor.

In either case, the control terminal of the power integrated circuit may be operatively connected to the drive circuit via a signal conditioning circuit. The signal conditioning circuit may comprise one or more of a level shifter, a buffer circuit, a filter, a logic circuit and/or a timing circuit.

The power integrated circuit may further comprise any one of more of the following components or circuits:
a Miller clamp HEMT;
a pull-down circuit;
a voltage regulator;
a current source;
a sensing load resistor;
a short-circuit detection circuit;
a sensing and protection circuit;
an over-current protection circuit;
an over-temperature protection circuit;
a drive circuit;
a start-up circuit;
an electrostatic discharge circuit;
a logic circuit;
a capacitor;
a resistor; and/or
a diode.

It will be understood that a diode as used herein may refer to any component configured to facilitate current flow in a forward direction and block current flow in a reverse direction. For example, the or a diode of the present disclosure may comprise or be substituted for any one or more of a p-n junction diode, a Schottky diode, a source-gate connected transistor, or any other suitable device.

According to a second aspect of the present disclosure there is provided a system comprising:

a power integrated circuit comprising:
at least one III-nitride high voltage high-electron-mobility transistor (power HEMT), the power HEMT comprising a heterojunction formed between a GaN layer and an AlGaN layer; and
a clamping transistor electrically connected between a gate terminal and a source terminal of the power HEMT;
a silicon chip co-packaged with the power integrated circuit, the silicon chip comprising:
a detection circuit electrically connected between a drain terminal and the source terminal of the power HEMT, wherein an output of the detection circuit is electrically connected to a gate terminal of the clamping transistor; and
wherein the detection circuit is configured to output a signal to turn-on the clamping transistor when a transient voltage greater than a threshold transient voltage is observed across the drain and the source terminals of the power HEMT.

The silicon chip may further comprise one or more of:
a voltage regulator;
a sensing load resistor;
a short-circuit detection circuit;
a sensing and protection circuit;
an over-current protection circuit;
an over-temperature protection circuit;
a drive circuit;
a start-up circuit;
an electrostatic discharge circuit; and/or
a logic circuit.

The power integrated circuit may be a power integrated circuit according to the first aspect of the disclosure.

### BRIEF DESCRIPTION OF THE DRAWINGS

The present disclosure will be understood more fully from the accompanying drawings, which however, should not be taken to limit the disclosure to the specific embodiments shown, but are for explanation and understanding only.

FIG. 1 shows a circuit schematic of an active Miller clamp circuit.

FIG. 2 shows a bridge leg circuit which comprises two power HEMTs and associated active Miller clamp HEMTs.

FIG. 3 shows another example of a half-bridge configuration for power devices.

FIG. 4 shows a circuit schematic of an example slew rate protection circuit according to the present disclosure.

FIG. 5 shows a circuit schematic of another example slew rate protection circuit according to the present disclosure.

FIG. 6 shows a circuit schematic of a further example slew rate protection circuit according to the present disclosure.

FIG. 7 shows a circuit schematic of a further example slew rate protection circuit according to the present disclosure.

FIG. 8 shows a circuit schematic of a further example slew rate protection circuit according to the present disclosure.

FIG. 9 shows a circuit schematic of an example detection protection circuit according to the present disclosure.

FIG. 10 shows a circuit schematic of another example detection circuit according to the present disclosure.

FIG. 11 shows a circuit schematic of a further example slew rate protection circuit according to the present disclosure.

FIG. 12 shows a schematic diagram of an example chip set according to the present disclosure.

### DETAILED DESCRIPTION OF THE PREFERRED EMBODIMENTS

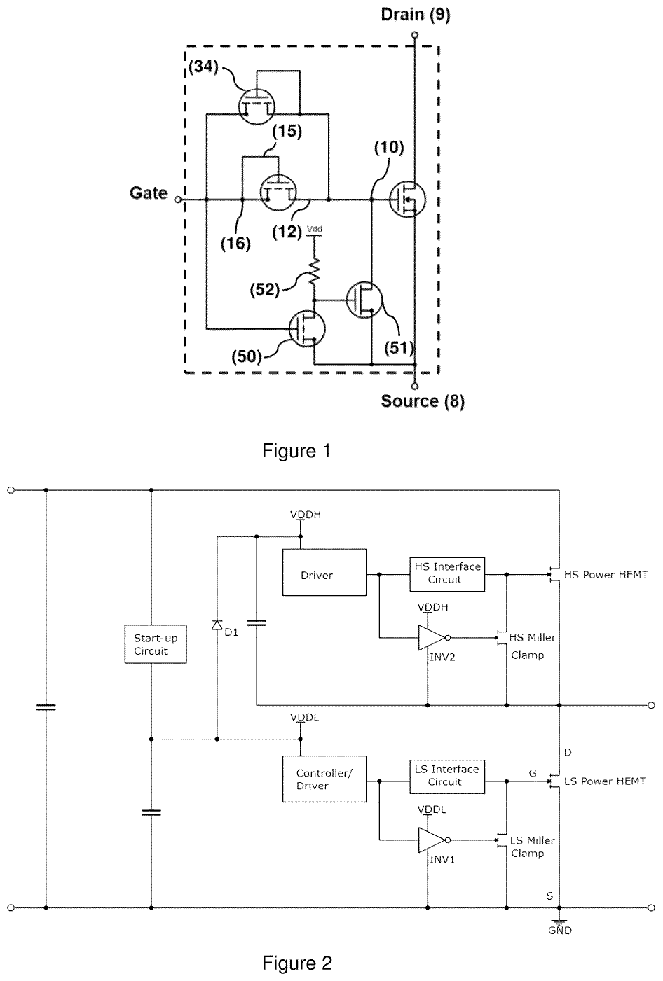

FIG. 1 shows a circuit schematic representation of an active Miller clamp circuit. FIG. 1 comprises a first transistor with source 16, drain 12 and gate 15 connections, a second transistor 34 and an active Miller clamp circuit comprising resistor 52, an actively switched low voltage enhancement mode transistor 50 and an actively switched depletion mode transistor 51. The active Miller clamp circuit is implemented to offer an additional pull-down network for the active device gate terminal 10 during the device turn-off transient. In operation the active Miller clamp uses the voltage bias of the external gate terminal (i.e. the terminal connected to the gate driver) to adjust the resistance of the actively switched transistor 51 such that a low resistance pull-down path is provided when the main power device is turning-off or is in the off-state. When the gate driver signal is high, the bias on the gate of the actively switched transistor 51 in the Miller clamp is low (therefore its resistance is high) and vice versa.

However, the active Miller clamp circuit may operate more effectively when the voltage (Vdd) is established to power the driving circuit of the active Miller clamp. In the absence of Vdd, high dV/dt values during switching transients across the device can potentially result in false turn-on of the transistor. In a typical half bridge topology this may result in shoot through.

A period where operation of the active Miller clamp is required for safe power integrated circuit (IC) operation but a necessary voltage supply is not yet established, may occur for example during the start-up of a power supply. An example of a power electronics circuit where this may occur is illustrated in FIG. 2.

FIG. 2 shows a circuit schematic representation of a bridge leg circuit. The circuit comprises two power HEMTs connected in a bridge leg configuration, their associated Miller clamps and Miller clamps driver circuits and their associated interface circuits. The circuits may be monolithically integrated as part of a power integrated circuit (IC). The power IC may be driven by a controller/driver circuit. Both the power IC and the controller/driver circuit require a voltage supply to operate (VDDL for low side circuits, VDDH for high side circuits), such that the driver of the power HEMT is powered by a voltage VDDL, VDDH for low side (LS) and high side (HS) respectively. The Miller clamp HEMTs are driven by an inverter which may also be powered by a voltage VDDL, VDDH for low side and high side respectively. The low side voltage supply may be provided by from the DC voltage rail through a start-up circuit. The high voltage supply may be provided from the low voltage supply via a bootstrap diode.

An interface circuit (or an auxiliary gate circuit) may be present between driver and the power HEMT as illustrated. During the start-up of the circuit, the low side voltage supply VDDL may be charged from the DC link through the start-up circuit. This can allow the low-side power HEMT to start switching according to the control signal by the controller/driver. For the first few switching cycles the high side voltage VDDH may not yet be established through a boot-strap diode, D1. In this scenario, therefore, fast slew rates may be observed at the mid-point of the bridge leg, due to the low side device switching, while the Miller clamp of the high side device is not yet powered by VDDH. This can lead to false turn-on of the high side device and shoot-though in the bridge-leg.

In other words, during start-up of the power electronics circuit in FIG. 2, the low voltage supply VDDL may be established before the high voltage supply VDDH. Therefore, the low side (LS) power HEMT may start switching before the high voltage supply VDDH is established. The high side (HS) power HEMT may therefore experience fast dv/dt transients across its drain-source terminals for example during turn-on of the low side power HEMT, potentially leading to false turn-on of the device as the active Miller clamp illustrated is not fully operational due to the absence of the high voltage supply, VDDH. Shoot through may also occur during this period if both the low side and high side power HEMT are ON at the same time.

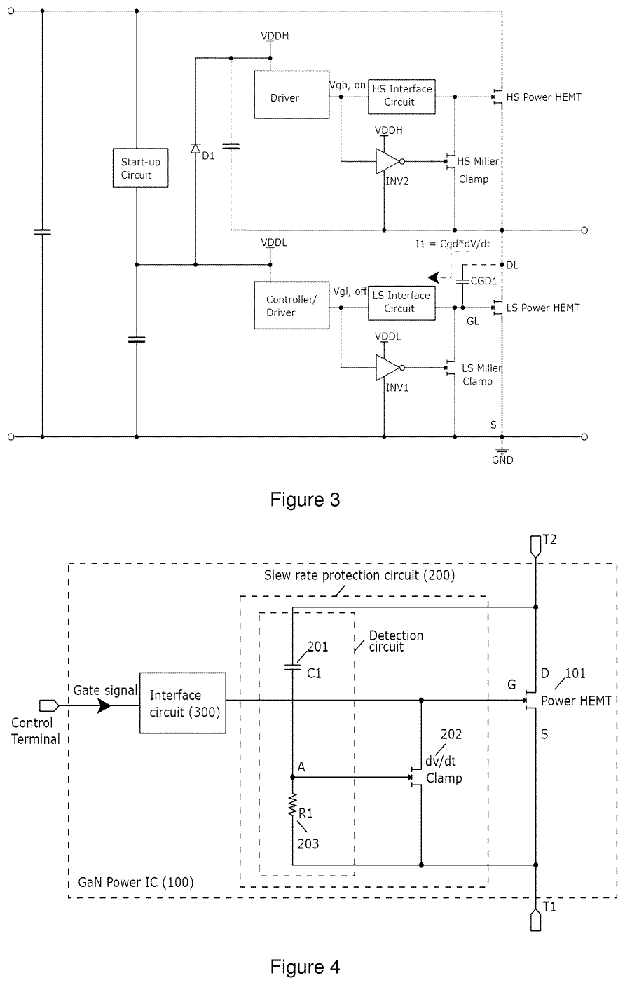

FIG. 3 shows another example of a half-bridge configuration of the power devices. When the gate of the high-side power device starts to switch ON, the high drain voltage of the HS device is translated at the source which in turn pulls-up the drain of the LS device. The Miller capacitance between the gate and the drain of the low side switch starts to charge and inject current to the LS gate. If the current injection into the gate is large enough to bring the gate voltage of the LS device above the device threshold voltage, parasitic turn-on can be observed resulting in lower efficiency or even device failure. As discussed above, an active Miller clamp between the gate and the source of the power device is one of technique to assist in mitigating or avoiding this spurious turn-on. However, in a scenario where the voltage supply (VDD) of the inverter driving the Miller clamp is not yet established and hence the active Miller clamp cannot turn on, the Miller clamp is not able to maintain the gate voltage below a desired threshold when a current spike through the Miller capacitance occurs.

FIG. 4 shows a circuit schematic example of a slew rate protection circuit 200 connected to a power HEMT device 101 and its associated circuits according to the present disclosure. The circuits may be monolithically integrated as part of a power integrated circuit (e.g. power IC 100) that has at least three terminals—a high voltage terminal (T2), a low voltage terminal (T1) and a control terminal. The power IC 100 may be driven by a controller/driver circuit that may be connected to the control terminal. The power HEMT 101 may be connected to the control terminal through an associated interface circuit 300. In an example according to the present disclosure, the power HEMT 101 is a high voltage lateral GaN HEMT. The interface circuit 300 is placed in front of the gate of the high voltage lateral GaN HEMT (e.g. connected between the control terminal and the gate of the power HEMT 101) to adapt the driving voltage of the control terminal to that suitable and allowable for the GaN HEMT. For example, the driving voltage on the gate terminal could range from 0V to 20 V while the driving voltage output by the interface circuit 300 (and therefore seen directly by the gate terminal of the lateral high voltage GaN HEMT) remains within a range of 0 to 7V.

The slew rate protection circuit 200 illustrated can operate without a voltage supply VDD. The slew rate protection circuit comprises a detection circuit (comprising capacitor 201 and resistor 203) and a transistor 202. The transistor 202 may be connected in a similar manner to a Miller clamp transistor i.e. it is connected between the gate and source terminal of the power HEMT 101 in order to facilitate a low parasitic connection between the two terminals when required. The transistor 202 is driven by the detection circuit which in this example comprises a passive differentiator circuit. If a fast transient (for example >100V/ns) is observed between the drain and source terminals of the power HEMT 101, the passive differentiator circuit will output the differential of the transient signal as an output. Thus, if a fast positive transient (for example >100V/ns) is observed (which in the circuits of FIG. 2 or 3 may trigger a false turn-on of the power HEMT through the Miller capacitance), the passive differentiator will output a positive spike to the gate of dv/dt clamp transistor 202. This can turn-on the dv/dt clamp transistor 202 and provide a low parasitic path to supress the false turn-on event. As such, the slew rate protection circuit 200 may also be called a dv/dt hold-off circuit.

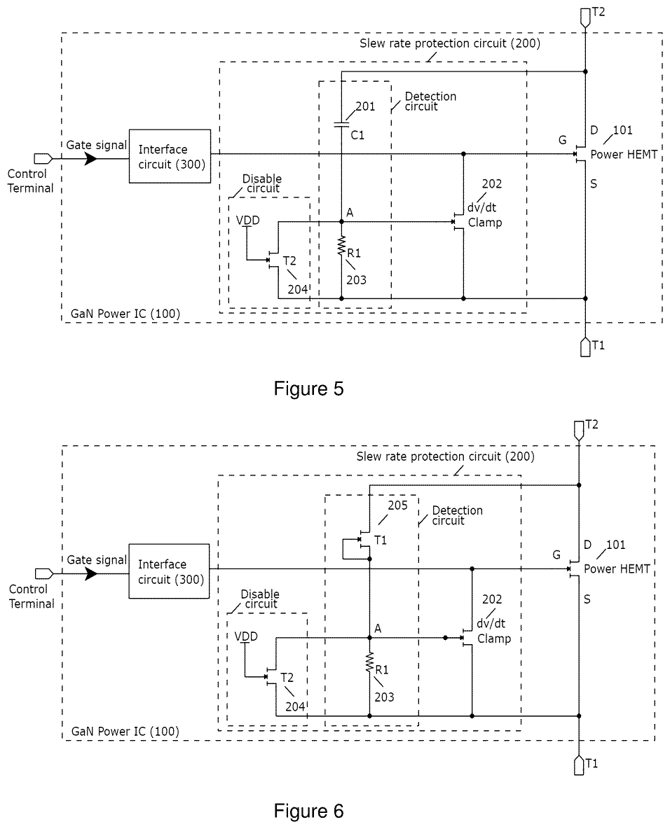

In implementations, it may be desirable to have the option of disabling the slew rate protection circuit. This may be implemented by including a disable circuit as illustrated in FIG. 5. The disable circuit comprises a transistor 204 with a gate terminal connected to a voltage supply VDD. When activated, the disable circuit enables the power IC 100 to ‘turn-off’ the functionality of the slew rate protection circuit 200. As a result, the power IC 100 may operate without any interference from the slew rate protection circuit 200 when the voltage supply VDD is established (and therefore when an active Miller clamp may be in normal operation). The disabling of the slew rate protection circuit 200 may facilitate a more robust overall operation of the power IC 100 as any potential false triggering of the slew rate protection circuit 200 (e.g. due to noise or other parasitic signals) may be reduced or avoided. While the disable circuit is depicted in several of the following embodiments described herein, it will be understood that this remains an optional feature in all such embodiments.

FIG. 6 illustrates another circuit schematic representation of the slew rate protections circuit 200. In this example the detection circuit comprises a resistor 203 and a high voltage enhancement mode transistor 205.

In this example, the high voltage enhancement mode transistor 205 is a source-gate connected HEMT and forms a detection circuit with the resistor 203 in series such that the mid-point serves as an output of the circuit detection circuit. The source-gate connected HEMT has an output capacitance, Coss which may operate in a similar manner to the capacitor 201 illustrated in previous embodiments. The source-gate connected HEMT may be more area efficient compared to a metal-insulator-metal (MIM) capacitor.

Advantageously, the source-gate connected transistor 205 may be a scaled down version (in terms of gate width or area) of the power HEMT 101. In this case, the HEMT 205 has a voltage dependent capacitance similar to that of the power HEMT 101. The output peak of the detection circuit may therefore be better matched in time with the spurious voltage peak on the gate of the power HEMT 101. Additionally, the scaled HEMT 205 can have the same high voltage rating as the power HEMT 101.

In another example, the Miller capacitance of the HEMT 205 may be engineered in order to produce a sufficient output to trigger the dv/dt clamp circuit before a drain-source dV/dt related spike is observed across the gate-source terminals of the power HEMT 101 through the Miller capacitance. This may be done by increasing the Miller capacitance of HEMT 205 at low drain-gate voltages Vgd (e.g. Vgd<50V) across its terminals through device cross-section engineering. For example, for a Vgd of less than about 50V, the Miller capacitance per unit width of HEMT 205 may be approximately or substantially equal to twice the Miller capacitance per unit width of the power HEMT 101.

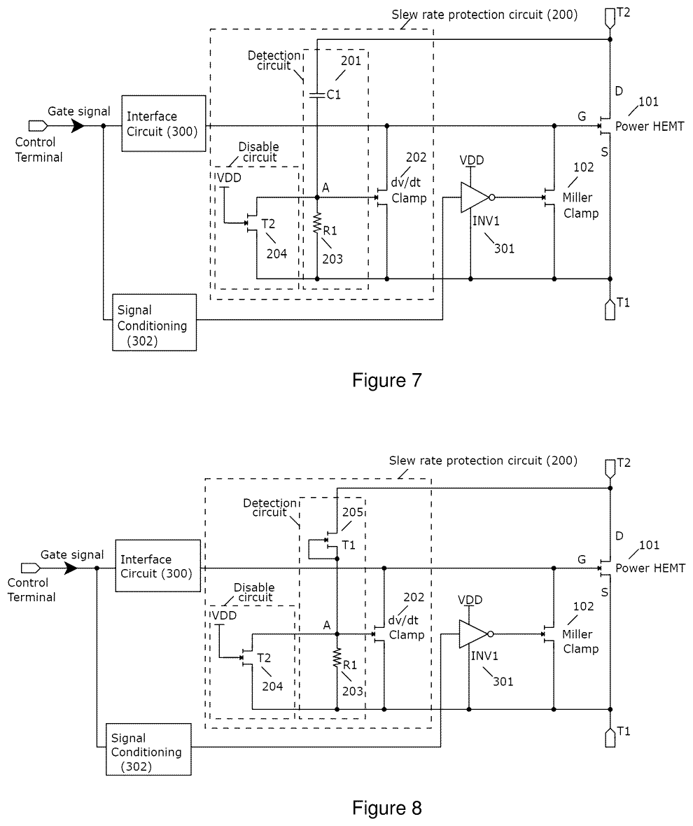

FIG. 7 illustrates a circuit schematic representation of the proposed disclosure where a slew rate protection circuit 200 is implemented composed of a detection circuit, a dv/dt clamp transistor 202 and an optional disable circuit. The detection circuit comprises a capacitor 201 and a resistor 203. The series combination of the capacitor 201 and resistor 203 form a detection circuit whose mid-point is connected to the gate of the dv/dt clamp transistor 202.

Additionally, FIG. 7 illustrates a Miller clamp transistor 102 driven by an inverter circuit 301 which is powered by a voltage supply VDD. The inverter circuit 301 may be operated by a conditioned version of the gate signal by passing the gate signal through a signal conditioning block or circuit 302. The signal conditioning block 302 may comprise one or more of a level shifter, a buffer circuit, a filter and/or a logic circuit. The entire circuit may be part of a GaN Power IC 100 as illustrated in previous embodiments.

The dv/dt clamp transistor 202 and the Miller clamp transistor 102 may be enhancement mode transistors. Alternatively, they may be depletion mode transistors, for example as described in U.S. Pat. No. 11,658,236.

In a situation where the Power HEMT 101 in FIG. 7 is a low-side device of a half-bridge configuration and is turned-off, if the high-side device is turned ON, the fast voltage transient at the drain of the low-side Power HEMT 101 charges the parasitic capacitance between the gate and the drain and can false turn-on the power HEMT 101. If, for some reason, VDD is not present, the Miller clamp 102 cannot turn ON and hence, cannot provide a low resistance path for the incoming current. Hence, the power HEMT 101 gate voltage may rise, leading to a false turn-on of the low-side power HEMT 101 and a shoot-through to occur. However, the slew rate protection circuit 200 can help to reduce the risk of or avoid a false turn-on of the low side Power HEMT 101 in this scenario. For example, the fast voltage transient across the drain/source of the power HEMT 101 can pull up node A via capacitance C1 of capacitor 201. This increases the voltage applied at the gate of the dv/dt clamp transistor 202 and can turn the transistor 202 ON. This in turn provides a low resistance path to the current from the power HEMT 101 Miller capacitance, and may therefore avoid a spike on the gate of the power HEMT 101. Thus, false turn-on events of the power HEMT 101 may be limited or avoided entirely.

The slew rate protection circuit 200 is also provided with a disable circuit comprising transistor 204 which may be modulated by the same voltage supply, VDD, powering the driving circuit of the Miller clamp transistor. When VDD is established, (i.e. the Miller clamp may be operational), the transistor 204 turns ON and the voltage at node A gets pulled down, thereby deactivating the slew rate protection circuit 200. Alternatively, transistor 204 may be modulated by the gate signal from the control terminal instead of the voltage supply VDD. When transistor 204 is modulated by the gate signal, the dv/dt clamp transistor 202 and miller clamp 102 may beneficially have stronger dv/dt immunity under normal operations.

FIG. 8 illustrates another circuit schematic representation of the proposed disclosure. As in FIG. 6, in this example the detection circuit comprises a resistor 203 and a source-gate connected high voltage enhancement mode transistor 205 in place of the capacitor 201, along with a Miller clamp transistor 102 driven by an inverter circuit 301 and a signal conditioning block or circuit 302 as described above in relation to FIG. 7.

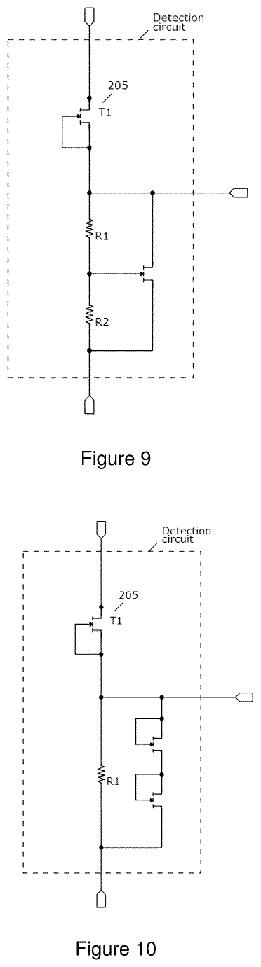

FIG. 9 illustrates an additional example of a detection circuit, suitable for use in any example slew rate protection circuit. It will therefore be understood that the detection circuit illustrated in FIG. 9 may replace the detection circuit depicted in any of e.g. FIGS. 4-8 described above. The detection circuit may comprise a threshold multiplier circuit in the place of resistor 203 as illustrated in previous embodiments. The threshold multiplier circuit may help to limit the maximum spike observed at the output of the detection circuit. This may further protect the gate of the transistor (e.g. dv/dt claim 202) connected at the output of the detection circuit.

FIG. 10 illustrates another additional example of a detection circuit, suitable for use in any example slew rate protection circuit. It will therefore be understood that the detection circuit illustrated in FIG. 10 may replace the detection circuit depicted in any of e.g. FIGS. 4-8 described above. In this example, a series of source-gate or drain-gate connected HEMTs are provided in parallel to a resistor (e.g. resistor 203) to help to limit the maximum spike observed at the output of the detection circuit. Two HEMTs are illustrated in this example, but more (e.g. 3, 4 or more HEMTS in series) or fewer (e.g. a single HEMT) can be used in other examples depending on the maximum desired allowable voltage at the output of the detection circuit.

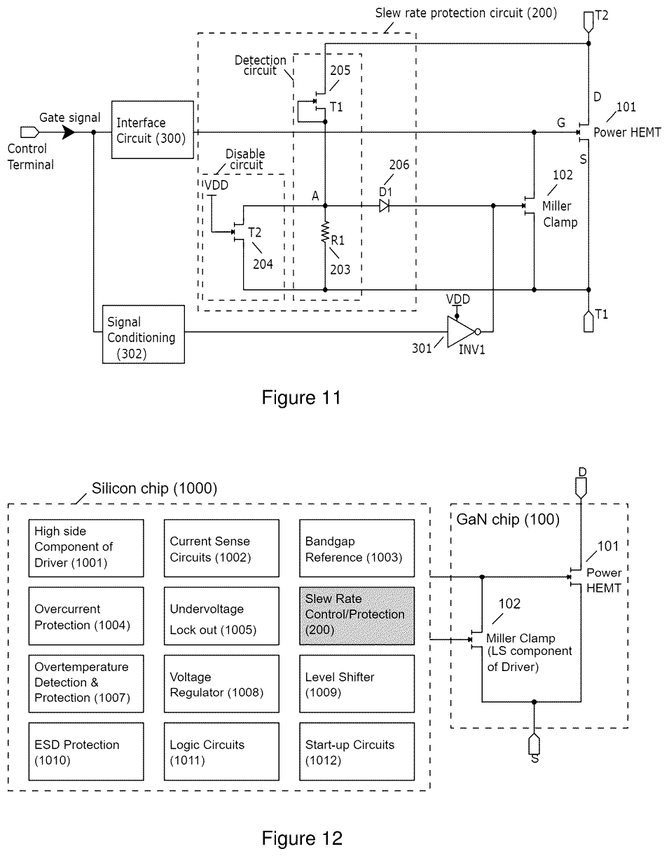

As shown in FIG. 11, the slew rate protection circuit 200 of the present disclosure can be integrated with an existing Miller clamp 102. In this configuration, the Miller clamp 102 can function as the dv/dt clamp. Hence, the overall circuit configuration depicted in FIG. 11 may comprise one fewer transistors compared to the configuration of FIGS. 7 and 8, which is beneficial in saving chip area. A diode 206 may be provided to facilitate the control of Miller clamp 102 by the slew rate protection circuit 200. In this example, the Miller clamp 102 may turn-on only when the voltage at node A is higher than the voltage at the output of the inverter 301. Hence, when for some reason VDD is not established and the drain of the power HEMT 101 observes a high voltage dv/dt transient (such that the inverter 301 is not able to activate the Miller Clamp 102), the slew rate protection circuit 200 may activate the Miller clamp 102. Once VDD is established, the transistor 204 switches ON, thereby pulling the node A down and reverse-biasing the diode 206. Thus, the slew rate protection circuit 200 is disabled and Miller clamp 102 operates based on the input from the driving circuit/control terminal.

The dv/dt clamp transistor 202 may have a much larger area in comparison to the diode 206. Hence, the use of diode 206 is beneficial in saving chip area. Additionally, the diode 206 may avoid or reduce power from the Miller clamp 102 being dissipated in the slew rate protection circuit 200 while the slew rate protection circuit 200 is disabled.

It will be understood that diode 206 may be any component configured to facilitate current flow in a forward direction and block current flow in a reverse direction. For example, the diode 206 may comprise or be substituted for any one or more of a p-n junction diode, a Schottky diode, a source-gate connected transistor, or any other suitable device.

FIG. 12 illustrates a silicon companion chip 1000 that may be co-packaged with a Power HEMT such as power HEMT 101. The Miller clamp 102 acting as the low side component of the driver may be monolithically integrated with the power HEMT 101. The slew rate protection circuit 200 can be incorporated in the silicon companion chip 1000. Additionally, the companion chip 1000 can provide various other functionality, such as voltage regulation 1008, voltage clamping action, undervoltage lockout 1005, high side drive 1001, current sensing 1002, bandgap referencing (1003), overcurrent protection 1004, overtemperature detection/protection 1007, level shifting 1009, electrostatic discharge (ESD) protection circuit 1010, logic circuits 1011 and start-up circuits 1012, among other sensing and protection features. It can have programmable functions and can be made in mix-signal processes which allow both digital and analogue components to be integrated.

The skilled person will understand that in the preceding description and appended claims, positional terms are made with reference to conceptual illustrations such as those shown in the appended drawings. These terms are used for ease of reference but are not intended to be of limiting nature. These terms are therefore to be understood as referring to the positioning of the components as shown in the accompanying schematic drawings.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the disclosure, whether alone or in any appropriate combination with any other feature disclosed or illustrated herein.

Many other effective alternatives will occur to the person skilled in the art. It will be understood that the disclosure is not limited to the described embodiments, but encompasses all the modifications which fall within the spirit and scope of the disclosure.

1. A power integrated circuit comprising:
at least one III-nitride high voltage high-electron-mobility transistor (power HEMT), the power HEMT comprising a heterojunction formed between a GaN layer and an AlGaN layer; and
a slew rate protection circuit comprising:
a clamping transistor electrically connected between a gate terminal and a source terminal of the power HEMT;
a detection circuit electrically connected between a drain terminal and the source terminal of the power HEMT, wherein an output of the detection circuit is electrically connected to a gate terminal of the clamping transistor; and
wherein the detection circuit is configured to output a signal to turn-on the clamping transistor when a transient voltage greater than a threshold transient voltage is observed across the drain and the source terminals of the power HEMT.

2. The power integrated circuit of claim 1, wherein the clamping transistor is an enhancement mode transistor.

3. The power integrated circuit of claim 1, wherein at least one of:
(i) the slew rate protection circuit comprises a disable circuit electrically connected to a voltage supply terminal, wherein the disable circuit is configured to disable the slew rate protection circuit when a voltage applied to the voltage supply terminal is greater than a threshold voltage; and
(ii) the slew rate protection circuit is monolithically integrated with the power integrated circuit.

4. The power integrated circuit of claim 3, wherein the disable circuit comprises a disable transistor, wherein:
a source terminal of the disable transistor is electrically connected to a source terminal of the clamping transistor;
a drain terminal of the disable transistor is electrically connected to the gate terminal of the clamping transistor; and
a gate terminal of the disable transistor is electrically connected to the voltage supply terminal.

5. The power integrated circuit of claim 1, wherein the detection circuit comprises a resistive element and a capacitive element connected in series, and wherein a midpoint between the resistive element and the capacitive element is electrically connected to the gate terminal of the clamping transistor.

6. The power integrated circuit of claim 5, wherein capacitive element comprises either:
a source-gate connected transistor; or
a capacitor.

7. The power integrated circuit of claim 6, wherein the capacitive element comprises the source-gate connected transistor, and wherein the source-gate connected transistor has a substantially identical structure to the power HEMT, and wherein the source-gate connected transistor is scaled to a smaller area or gate perimeter than the power HEMT by a scale factor X, where X is larger than 1.

8. The power integrated circuit of claim 1, wherein the resistive element comprises one or more of:
a resistor; and
a threshold multiplier circuit.

9. The power integrated circuit of claim 8, wherein the resistive element comprises the resistor, and wherein detection circuit further comprises one or more transistors connected in parallel to the resistor, wherein the one or more transistors comprise a series of sources-gate connected or drain-gate connected transistors.

10. The power integrated circuit of claim 1, comprising a component electrically connected between the output of the detection circuit and the gate terminal of the clamping transistor, wherein the component is configured to block or limit a flow of current in a reverse direction.

11. The power integrated circuit of claim 10, wherein the component is a diode.

12. The power integrated circuit of claim 1, comprising:
an interface circuit electrically connected between a control terminal of the power integrated circuit and the gate terminal of the power HEMT.

13. The power integrated circuit of claim 12, wherein the interface circuit is either:
(i) an external circuit connected to the power integrated circuit; or
(ii) is monolithically integrated with the power integrated circuit.

14. The power integrated circuit of claim 1, comprising either:
(i) a drive circuit electrically connected to the gate terminal of the clamping transistor; or
(ii) a second clamp transistor electrically connected between a gate terminal and a source terminal of the power HEMT; and
a drive circuit electrically connected to the gate terminal of the second clamp transistor.

15. The power integrated circuit of claim 14 wherein at least one of:
(i) the slew rate protection circuit comprises a disable circuit electrically connected to a voltage supply terminal, wherein the disable circuit is configured to disable the slew rate protection circuit when a voltage applied to the voltage supply terminal is greater than a threshold voltage, and the drive circuit is operated or powered by the voltage applied to the voltage supply terminal;
(ii) the drive circuit is an inverter circuit; and/or
(iii) the drive circuit is electrically connected to a control terminal of the power integrated circuit via a signal conditioning circuit.

16. The power integrated circuit of claim 15, wherein the signal conditioning circuit comprises one or more of a level shifter, a buffer circuit, a filter, a logic circuit and/or a timing circuit.

17. The power integrated circuit of claim 1, wherein the threshold transient voltage is 100V per nanosecond.

18. A power integrated circuit of claim 1, comprising one of more of:
a Miller clamp HEMT;
a pull-down circuit;
a voltage regulator;
a current source;
a sensing load resistor;
a short-circuit detection circuit;
a sensing and protection circuit;
an over-current protection circuit;
an over-temperature protection circuit;
a drive circuit;
a start-up circuit;
an electrostatic discharge circuit;
a logic circuit;
a capacitor;
a resistor; and/or
a diode.

19. A system comprising:
a power integrated circuit comprising:
at least one III-nitride high voltage high-electron-mobility transistor (power HEMT), the power HEMT comprising a heterojunction formed between a GaN layer and an AlGaN layer; and
a clamping transistor electrically connected between a gate terminal and a source terminal of the power HEMT;
a silicon chip co-packaged with the power integrated circuit, the silicon chip comprising:
a detection circuit electrically connected between a drain terminal and the source terminal of the power HEMT, wherein an output of the detection circuit is electrically connected to a gate terminal of the clamping transistor; and
wherein the detection circuit is configured to output a signal to turn-on the clamping transistor when a transient voltage greater than a threshold transient voltage is observed across the drain and the source terminals of the power HEMT.

20. The system of claim 19, wherein the silicon chip further comprises one or more of:
a voltage regulator;
a sensing load resistor;
a short-circuit detection circuit;
a sensing and protection circuit;
an over-current protection circuit;
an over-temperature protection circuit;
a drive circuit;
a start-up circuit;
an electrostatic discharge circuit; and/or
a logic circuit.
